(19) United States
(12) Patent Application Publication
(10) Pub. No.: US 2013/0328199 A1
(43) Pub. Date: Dec. 12, 2013

(54) SEMICONDUCTOR DEVICE WITH SPACERS FOR CAPPING AIR GAPS AND METHOD FOR FABRICATING THE SAME

(71) Applicant: SK HYNIX INC., Gyeonggi-do (KR)

(72) Inventors: Hyo-Jun YUN, Gyeonggi-do (KR); Sei-Jin KIM, Gyeonggi-do (KR); Hae-Il SONG, Gyeonggi-do (KR)

(73) Assignee: SK HYNIX INC., Gyeonggi-do (KR)

(21) Appl. No.: 13/720,199

(22) Filed: Dec. 19, 2012

(30) Foreign Application Priority Data
Jun. 7, 2012 (KR) 10-2012-0060959

(51) Int. Cl. H01L 23/498; H01L 21/02

(52) U.S. Cl. CPC H01L 23/49866; H01L 23/498; H01L 21/02697
USPC 257/754; 257/734; 438/652

(57) ABSTRACT

A method for fabricating memory device includes forming a bit line pattern including a first conductive layer and a hard mask stacked over a substrate, forming a sacrificial layer on sidewalls of the bit line pattern, forming a second conductive layer in contact with the sacrificial layer and adjacent to the bit line pattern, recessing the second conductive layer, forming an air gap between the recessed second conductive layer and the first conductive layer by removing the sacrificial layer, and forming an air gap capping layer on sidewalls of the hard mask to cap entrance of the air gap.

### CROSS-REFERENCE TO RELATED APPLICATIONS

The present application claims priority of Korean Patent Application No. 10-2012-0060959, filed on Jun. 7, 2012, which is incorporated herein by reference in its entirety.

### BACKGROUND

1. Field

Exemplary embodiments of the present invention relate to a semiconductor device fabrication method, and more particularly, to a semiconductor device having air gaps for a low dielectric constant to solve the problem caused by the air gaps, and a method for fabricating the semiconductor device.

2. Description of the Related Art

Semiconductor devices generally use an oxide layer and a nitride layer as an insulation layer. The oxide layer and the nitride layer, however, do not have a dielectric constant to satisfy the characteristics of the semiconductor devices in which patterns and lines are becoming finer and finer. To solve this concern, researchers are in the process of developing satisfactory semiconductor device characteristics by forming air gaps having a low dielectric constant in the semiconductor device.

A semiconductor device, such as Dynamic Random Access Memory (DRAM), performs an electrical operation of a capacitor and a bit line through a source/drain contact. Since a storage node contact (SNC) and the bit line (including a bit line contact) have to be formed within a small area, the storage node contact (SNC) and the bit line are laid adjacent to each other with a spacer between them. Typically, a nitride layer, such as a silicon nitride layer, may be used as the spacer. Since the silicon nitride layer has a high dielectric constant, the silicon nitride layer is not effective in suppressing the parasitic capacitance (Cb) between the bit line and the storage node contact (SNC). Therefore, the parasitic capacitance (Cb) between the bit line and the storage node contact (SNC) becomes great, so that the sensing margin of a bit line sense amplifier is decreased. To solve this concern, the applicant of the present invention have suggested a method for forming air gaps between the bit line and the storage node contact (SNC), which is disclosed in Korean Patent Application No. 10-2010-0140493.

However, if the top of each air gap is not completely capped, materials such as metal penetrate into the air gaps in the subsequent process to cause failure. Even if the air gaps are capped, when an air gap capping layer is formed on top of a bit line hard mask as described in the conventional technology (e.g., Korean Patent Application No. 2010-0140493) the air gap capping layer may be damaged during the subsequent process, thus opening the air gaps.

### SUMMARY

Exemplary embodiments of the present invention are directed to a semiconductor device that may improve the margin of a subsequent process by stably capping air gaps, and a method for fabricating the semiconductor device.

Other embodiments of the present invention are directed to a semiconductor device that may improve the sensing margin of cell data by minimizing the parasitic capacitance (Cb) between bit lines and storage node contacts, and a method for fabricating the semiconductor device.

In accordance with an embodiment of the present invention, a semiconductor device includes a first conductive layer, a hard mask stacked over the first conductive layer, a second conductive layer formed adjacent to a side of the conductive layer, a third conductive layer stacked over the second conductive layer, an air gap formed between the first conductive layer and the second conductive layer, and an air gap capping layer formed between the hard mask and the third conductive layer, and capping entrance of the air gap.

In accordance with another embodiment of the present invention, a semiconductor device includes a bit line pattern including a bit line and a hard mask stacked over the bit line, a storage node contact including a first conductive layer and a second conductive layer stacked over the first conductive layer, the storage node contact being formed adjacent to side of the bit line pattern, an air gap formed between the bit line and the first conductive layer, and an air gap capping layer formed between the hard mask and the second conductive layer, the air gap capping layer capping entrance of the air gap.

In accordance with yet another embodiment of the present invention, a method for fabricating a semiconductor device includes forming a bit line pattern including a first conductive layer and a hard mask stacked over a substrate, forming a sacrificial layer on sidewalls of the bit line pattern, forming a second conductive layer in contact with the sacrificial layer and adjacent to the bit line pattern, recessing the second conductive layer, forming an air gap between the recessed second conductive layer and the first conductive layer by removing the sacrificial layer, and forming an air gap capping layer on sidewalls of the hard mask to cap entrance of the air gap.

### BRIEF DESCRIPTION OF THE DRAWINGS

FIG. 1 is a cross-sectional view illustrating a semiconductor device in accordance with an embodiment of the present invention,

FIG. 2 is a cross-sectional view illustrating a memory device to which the suggested technology shown in FIG. 1 is applied,

FIGS. 3A to 3G are cross-sectional views illustrating a process of fabricating the memory device shown in FIG. 2 in accordance with an embodiment of the present invention.

### DETAILED DESCRIPTION

Exemplary embodiments of the present invention will be described below in more detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Throughout the disclosure, like reference numerals refer to like parts throughout the various figures and embodiments of the present invention.

The drawings are not necessarily to scale and in some instances, proportions may have been exaggerated in order to clearly illustrate features of the embodiments. It should be readily understood that the meaning of “on” and “over” in the present disclosure should be interpreted in the broadest manner such that “on” not only means “directly on” something but also include the meaning of “on” something with an intermediate feature or a layer therebetween, and that ‘over not only means the meaning of “over” something may also include the meaning it is “over” something with no intermediate feature or layer therebetween (i.e., directly on something).

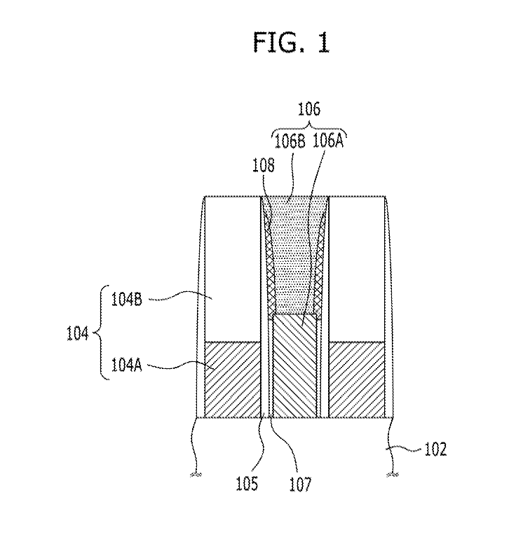

FIG. 1 is a cross-sectional view illustrating a semiconductor device in accordance with an embodiment of the present invention.

Referring to FIG. 1, a first pattern 104 is formed over a substrate. The first pattern 104 may be a stacked structure where a first conductive layer 104A and a hard mask 104B are stacked. The hard mask 104B is an insulation layer. A second pattern 106 is formed adjacent to the first pattern 104. The second pattern 106 may be a stacked structure where a second conductive layer 106A and a third conductive layer 106B are stacked. An air gap 107 is formed between the first conductive layer 104A and the second conductive layer 106A. An air gap capping layer 108 for capping the entrance of the air gap 107 is formed between the hard mask 104B and the third conductive layer 106B. The air gap capping layer 108 may be an insulation layer. The first pattern 104 may further include insulation layer spacers 105 formed on its sidewalk.

The semiconductor device in accordance with the embodiment of the present invention includes the air gap 107 and the air gap capping layer 108 vertically stacked between the first pattern 104 and the second pattern 106, and the air gap 107 and the air gap capping layer 108 are formed between the first pattern 104 and the second pattern 106. Since the air gap 107 are formed in a lower structure of a structure where the first conductive layer 104A exists, the parasitic capacitance between the first conductive layer 104A and the second conductive layer 106A may be minimized. Since the air gap capping layer 108 is formed in the shape of sidewall spacers between the hard mask 1048 and the third conductive layer 1068, the air gap capping layer 108 protects the inside of the air gap 107 from a material such as metal that penetrates and causes a failure in the subsequent process. For example, the first conductive layer 104A is a bit line layer of a memory device, and the second and third conductive layers are storage node contacts. Herein, although a portion of each storage node contact is lost during a subsequent process for forming storage nodes in the upper portion of the storage node contact, since there are the air gap 107 in the lower portion and the air gap capping layer 108 is formed with a sufficient height over the air gap 107, the entrance of the air gap 107 is not opened. Therefore, the inside of the air gap 107 is protected from the penetration of a storage node material, such as metal, which is described in detail below.

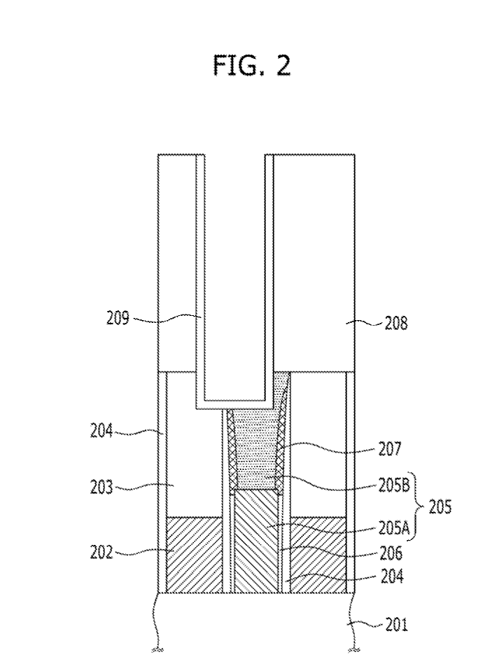

FIG. 2 is a cross-sectional view exemplarily illustrating a memory device to which the suggested technology is applied. The drawing shows a structure where air gap and an air gap capping layer are formed between bit lines and storage node contacts.

Referring to FIG. 2, bit lines 202 and a hard mask 203 are stacked over a substrate 201. The bit lines 202 are formed of a conductive material, and the bit lines 202 may be formed as a single layer of polysilicon or metal or a stacked layer of a polysilicon layer and a metal layer. When the bit lines 202 are formed as a stacked layer of a polysilicon layer and a metal layer, a barrier metal layer may be additionally formed between the polysilicon layer and the metal layer. Examples of the metal used for forming the bit lines 202 include tungsten (W) and aluminum (Al); and examples of the barrier metal for the barrier metal layer include tungsten silicon nitride (WSiN), tungsten nitride (WN), titanium (Ti), and titanium nitride (TiN). The hard mask 203 is an insulation layer. The hard mask 203 may be formed as a single layer of an oxide layer or a nitride layer, or a stacked layer of an oxide layer and a nitride layer.

Insulation layer spacers 204 may be formed on the sidewalls of the bit lines 202 and the hard mask 203. The insulation layer spacers 204 may be formed as single spacers with an oxide layer or a nitride layer or dual spacers with an oxide layer and a nitride layer.

Storage node contacts 205 are formed over the substrate 201 adjacent to the sides of the bit lines 202. The storage node contacts 205 are formed by stacking a second conductive layer 205A and a third conductive layer 2058. In FIG. 2, the storage node contacts 205 are illustrated to have two layers, but the drawing just simplifies the structure of the storage node contacts 205. The second conductive layer 205A may be formed of one selected from the group including polysilicon, silicide, metal, and a combination thereof. The third conductive layer 2058 may be a metallic thin film, and it may be of a stacked structure of titanium (Ti)/titanium nitride (TiN)/tungsten (W). In other words, Ti/TiN may be used as a barrier metal, and an electrode may be formed of tungsten (W) over the barrier metal.

Air gap 206 are formed in the lower portion of the space between the insulation layer spacers 204 and the storage node contacts 205, and an air gap capping layer 207 is formed in the upper portion of the space. The air gap 206 is disposed between the bit lines 202 and the second conductive layer 205A of the storage node contacts 205. The air gap capping layer 207 is formed in the shape of sidewall spacer between the hard mask 203 and the third conductive layer 205B and caps the entrance of the air gap 206. The air gap capping layer 207 is formed of an insulation material, such as an oxide and/or a nitride.

Storage nodes 209 are formed over the storage node contacts 205. The storage nodes 209 may be formed on the internal walls of the openings of an insulation layer 208. When the insulation layer 208 is etched to form the openings, the surface of the lower structure of the insulation layer 208 is damaged. The air gap capping layer 207 is damaged as well. Since the air gap capping layer 207 is formed vertically with a sufficient height between the hard mask 203 and the third conductive layer 2058, the air gap 206 are not opened even though a portion of the air gap capping layer 207 is damaged. Therefore, when the storage nodes 209 are deposited in the openings of the insulation layer 208, an impurity such as a storage node material does not penetrate into the air gap 205. In short, the air gap 206 is stably protected. As a result, not only the process margin for a subsequent process is secured, but also the parasitic capacitance between the bit lines 202 and the storage node contacts 205 may be minimized due to the formation of the stable air gap 206.

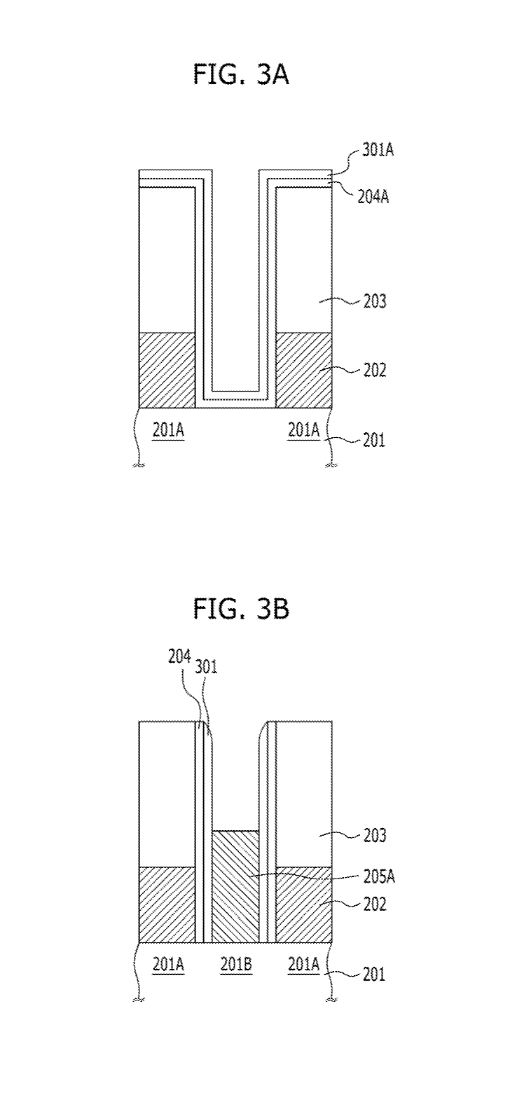

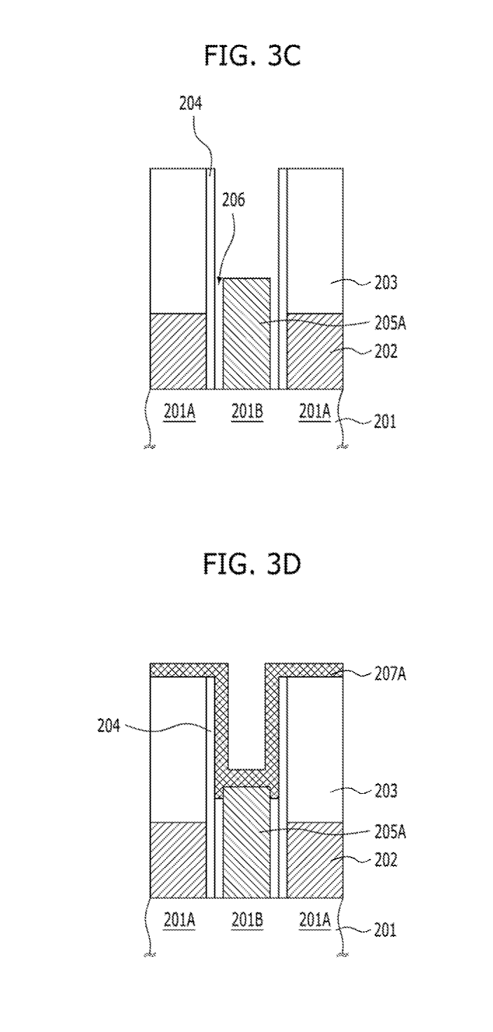

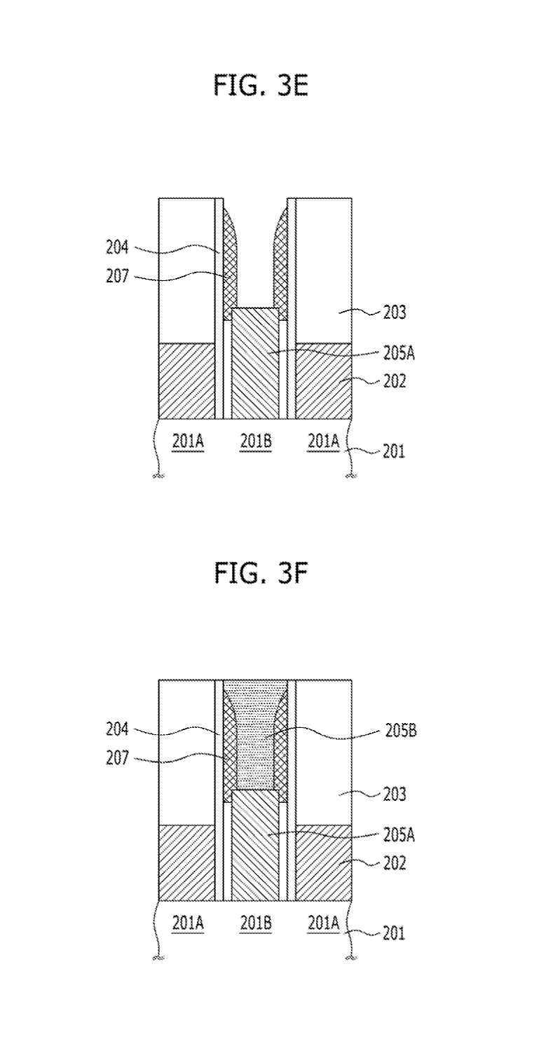

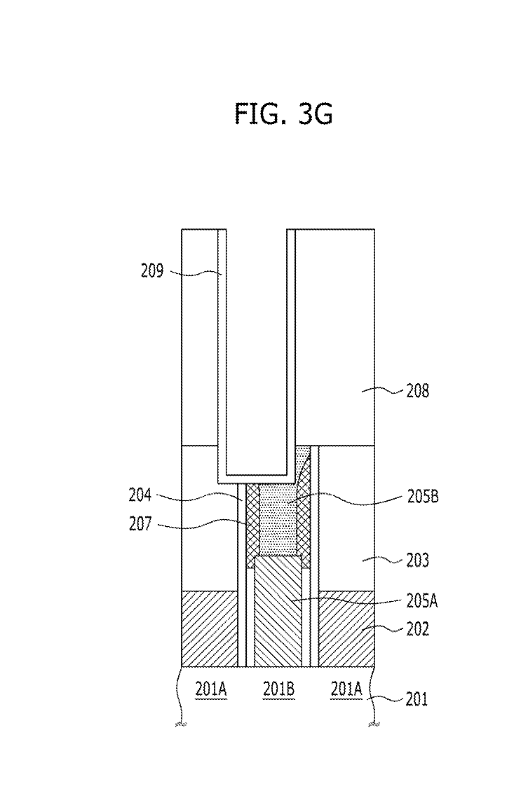

FIGS. 3A to 3G are cross-sectional views illustrating a process of fabricating the memory device shown in FIG. 2 in accordance with an embodiment of the present invention. The same reference numerals appearing in FIG. 2 refer to the same constituent elements of FIG. 3.

Referring to FIG. 3A, patterns where bit lines 202 and a hard mask 203 are stacked are formed over a substrate which is obtained after a predetermined process. First areas 201A of the substrate with which the bit lines 202 are to be coupled may be active regions or landing plugs. Subsequently, an insulation layer 204A and a sacrificial layer 301A are sequentially deposited over the substrate structure where the bit lines 202 and the hard mask 203 are formed. The insulation layer 204A may be a nitride layer. The sacrificial layer 301A may be one selected from the group including a titanium nitride layer, a tungsten oxide layer, an aluminum oxide (Al 03) layer, a silicon (Si) layer, and a combination thereof.

Referring to FIG. 35, insulation layer spacers 204 and sacrificial layer spacers 301 are formed on the sidewalls of the stacked structure of the bit lines 202 and the hard mask 203 by etching the sacrificial layer 301A and the insulation layer 204A. As a result, second regions 201B with which storage node contacts are to be coupled are exposed. The second regions 2015 may be active regions or landing plugs. Subsequently, a second conductive layer 205A is formed between the patterns that have a stacked structure of the bit lines 202 and the hard mask 203 by depositing a conductive layer on the profile of the substrate structure and performing an etch-back process. Herein, the upper portion of the second conductive layer 205A is not horizontally disposed in the upper portion of the hard mask 203, and sufficiently recessed to be adjacent to the bit lines 202 in the lower portion of the hard mask 203. The second conductive layer 205A may be formed of one selected from the group including polysilicon, silicide, metal, and a combination thereof.

Referring to FIG. 3C, air gap 206 are formed between the bit lines 202 and the second conductive layer 205A by removing the sacrificial layer spacers 301. To be specific, since the sacrificial layer spacers 301 are removed, the air gap 206 are formed adjacent to the bit lines 202 between the insulation layer spacers 204 and the second conductive layer 205A. The air gap 206 may be formed to have a linewidth of approximately 5 nm to obtain the maximal dielectric constant. The linewidth of the air gap 206 depends on the deposition thickness of the sacrificial layer 301A, and the height of the air gap 206 depends on the extent that the second conductive layer 205A is recessed. Therefore, the deposition thickness of the sacrificial layer 301A and the extent that the second conductive layer 205A is recessed may be decided in consideration of the height and linewidth of the air gap 206.

A process for removing the sacrificial layer spacers 301 may be a wet etch process or a dry etch process. When the sacrificial layer spacers 301 is removed, the insulation layer spacers 204, a hard mask 203, and the second conductive layer 205A have selectivity so that they are not damaged. When the sacrificial layer spacers 301 are a titanium nitride layer, the sacrificial layer spacers 301 may be removed through a wet etch process using a mixed solution of sulfuric acid (H₂SO₄) and hydrogen peroxide (H₂O₂)

Referring to FIG. 3D, an air gap capping thin film 207A is formed on the profile of the substrate structure where the air gap 206 are formed. Herein, the deposition thickness of the air gap capping thin film 207A is thick enough to cover the entrance of the air gap 206. When the air gap capping thin film 207A is deposited, the air gap 206 has a very thin space. Therefore, only the entrance portion of the air gap 206 is filled, and the air gap capping thin film 207A does not fill deep inside the air gap 206. According to an embodiment of the present invention, the air gap capping thin film 207A may be a nitride layer formed through a Plasma Enhanced Chemical Vapor Deposition (PECVD) process. The air gap capping thin film 207A is of an insulation material, such as an oxide and/or a nitride,

Referring to FIG. 3E, an air-gap capping layer 207 is formed as spacers on the sidewalls of the hard mask by etching the air gap capping thin film 207A.

Referring to FIG. 3F, a third conductive layer 205B is formed by depositing a metallic conductive material on the profile of the substrate structure and performing an etch-back process or a polishing process until the hard mask 203. After all, the air-gap capping layer 207 exists in the shape of sidewall spacer between the insulation layer spacers 204 on the sidewalls of the hard mask 203 and the third conductive layer 205B, and the air-gap capping layer 207 hermetically seals the entrance of the air gap 206 under the air-gap capping layer 207.

The third conductive layer 205B may have a stacked structure including titanium (Ti), titanium nitride (TiN), and tungsten (W). In other words, Ti/TiN may be used as the barrier metal, and an electrode may be formed of tungsten (W) over the barrier metal of Ti/TiN. Also, when the second conductive layer 205A is a polysilicon layer, a third conductive layer 205B may be formed after a silicide thin film, such as a cobalt silicide, is formed over the polysilicon layer.

Referring to FIG. 3G an insulation layer 208 is formed on the profile of the substrate structure, and openings are formed in the areas where storage nodes are to be formed, and then storage nodes 209 are formed on the internal walls of the openings. The openings are not exactly aligned with storage node contacts 205 and some of the openings are misaligned. When the insulation layer 208 for forming the openings is etched, the under layers of the insulation layer 208 are removed to some depth. Herein, although the air gap capping layer 207 is removed to some thickness, the air gap 206 exist only in the lower portion of the air gap capping layer 207, which is not affected from the partial removal of the air gap capping layer 207, and since the air gap capping layer 207 exists with a sufficient height over the air gap 206, the entrance of the air gap 205 is not opened. Therefore, the material of the storage nodes 209, e.g., metal, may not penetrate into air gap 206.

The above-described technology may be applied to a Dynamic Random Access Memory (DRAM) device, a Static Random Access Memory (SRAM) device, a flash memory, a ferroelectric Random Access Memory (FeRAM) device, a Magnetic Random Access Memory (MRAM) device, a Phase Change Random Access Memory (PCRAM) device and so forth.

The semiconductor device described above may be applied not only to the computing memories of a desktop computer, laptop computer and server but also to graphic memories of diverse specifications and mobile memories, which is drawing attention due to the recent development in mobile telecommunication. Also, the semiconductor device described above may be applied not only to portable storages, such as a memory stick, a Multi-Media Card (MMC), a Secure Digital (SD) card, CF an xD picture card, a Universal Serial Bus (USB) flash device, but also to diverse digital applications, such as MP3 (Moving Picture Experts Group (MPEG) Layer 3) players, Portable Multimedia Player (PMP), digital cameras, camcorders, and mobile phones. Also, a semiconductor device may be applied to a Multi-Chip Package (MCP), a disk-on-chip (DOC) an embedded device and the like. In addition, the semiconductor device according to an embodiment of the present invention may be used for a CMOS image sensor (CIS) to be applied to diverse areas, such as camera phones, web cameras, medical photographing equipment, and so on,

According to an embodiment of the present invention, a semiconductor device includes thin spacers where an air gap and an air gap capping layer are vertically stacked between neighboring patterns. The air gap is formed only in the lower portion of a structure where a first conductive layer, such as bit lines, exists, and the air gap capping layer is formed with a sufficient height over the lower portion of the structure. Therefore, although the air gap capping layer is lost to some extent during a subsequent process, such as a storage node forming process, the entrance to the air gap is not opened. As a result, the inside of the air gap is prevented from being filled with an impurity, such as metal.

While the present invention has been described with respect to the specific embodiments, it will be apparent to those skilled in the art that various changes and modifications may be made without departing from the spirit and scope of the invention as defined in the following claims.

What is claimed is:

1. A semiconductor device, comprising.
a first conductive layer;
a hard mask stacked over the first conductive layer;
a second conductive layer formed adjacent to a side of the conductive layer;
a third conductive layer stacked over the second conductive layer;
an air gap formed between the first conductive layer and the second conductive layer; and
an air gap capping layer formed between the hard mask and the third conductive layer, and capping entrance of the air gap.

2. The semiconductor device of claim 1, further comprising:
an insulation layer spacers formed on sidewalls of the first conductive layer and the hard mask.

3. A semiconductor device, comprising:
a bit line pattern including a bit line and a hard mask stacked over the bit line;
a storage node contact including a first conductive layer and a second conductive layer stacked over the first conductive layer, the storage node contact being formed adjacent to side of the bit line pattern;
an air gap formed between the bit line and the first conductive layer; and
an air gap capping layer formed between the hard mask and the second conductive layer, the air gap capping layer capping entrance of the air gap.

4. The semiconductor device of claim 3, further comprising:
a storage node formed over the second conductive layer.

5. The semiconductor device of claim 3, wherein the first conductive layer includes a polysilicon layer.

6. The semiconductor device of claim 5, wherein the second conductive layer includes a metallic thin film.

7. The semiconductor device of claim 6, further comprising:
a silicide layer interposed between the polysilicon layer and the metallic thin film.

8. The semiconductor device of claim 3, wherein the second conductive layer comprises a stacked layer of titanium (Ti) and titanium nitride (TiN), and tungsten (W).

9. The semiconductor device of claim wherein the air gap capping layer is formed of an insulation material.

10. The semiconductor device of claim 9, wherein the air gap capping layer includes a nitride layer obtained through a Plasma Enhanced Chemical Vapor Deposition (PECVD) process.

11. The semiconductor device of claim 3, wherein the bit line pattern further includes:
an insulation layer spacer formed on sidewalls of the bit line and the hard mask.

12. The semiconductor device of claim 11, herein the insulation layer spacers is formed of a nitride layer.

13. A method for fabricating a semiconductor device, comprising:
forming a bit line pattern including a first conductive layer and a hard mask stacked over a substrate;
forming a sacrificial layer on sidewalls of the bit line pattern;
forming a second conductive layer in contact with the sacrificial layer and adjacent to the bit line pattern;
recessing the second conductive layer;
forming an air gap between the recessed second conductive layer and the first conductive layer by removing the sacrificial layer; and
forming an air gap capping layer on sidewalk of the hard mask to cap entrance of the air gap.

14. The method of claim 13, further comprising:
forming a third conductive layer over the second conductive layer by depositing a conductive material on the profile of the substrate where the air gap capping layer is formed and performing an etch-back process.

15. The method of claim 13, wherein the sacrificial layer is one selected from the group comprising a titanium nitride layer, a tungsten oxide layer, an aluminum oxide layer (Al₂O₃), a silicon (Si) layer, and a combination thereof.

16. The method of claim 13, wherein the sacrificial layer is a titanium nitride layer, and the sacrificial layer is removed using a mixed solution of sulfuric acid (H₂SO₄) and hydrogen peroxide (H₂O₂).

17. The method of claim 13, wherein the air gap capping layer is formed of a nitride layer obtained through a Plasma. Enhanced Chemical Vapor Deposition (PECVD) process.

18. The method of claim 14, wherein the first conductive layer is a bit line, and the second conductive layer and the third conductive layer form a storage node contact.

19. The method of claim 13, further comprising
forming an insulation layer spacer on sidewalls of a stacked structure where the first conductive layer and the hard mask are stacked, before the forming of the sacrificial layer.

20. The method of claim 9, wherein the insulation layer spacers are formed of a nitride layer.
